(19) United States
(12) Patent Application Publication
(10) Pub. No.: US 2006/0071244 A1
(43) Pub. Date: Apr. 6, 2006

(54) Switching or amplifier device, in particular transistor

(75) Inventors: Martin Gutsche, Dorfen (DE); Cay-Uwe Pinnow, Munchen (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/188,107

(22) Filed: Jul. 25, 2005

(30) Foreign Application Priority Data
Aug. 2, 2004 (DE) 10 2004 037 450.3

(51) Int. Cl. H01L 29/768

(52) U.S. Cl. 257/250

(57) ABSTRACT

The invention relates to a method for operating a switching or amplifier device (11, 111), and to a switching or amplifier device (11, 111) comprising:
an active material (13, 113) adapted to be placed in a more or less conductive state by means of appropriate switching processes; and
at least three electrodes or contacts (12a, 12b, 12c).

### CLAIM FOR PRIORITY

This application claims priority to German Application No. 10 2004 037 450.3 filed Aug. 2, 2004, which is incorporated herein, in its entirety, by reference.

The invention relates to a switching or amplifier device, in particular a transistor, and a method for operating a switching or amplifier device.

Conventional transistors serve to amplify or switch a signal.

Semiconductor bipolar transistors, e.g. silicon or germanium transistors (of the pnp or npn type) comprise three contacts and consist of two back to back diodes that have a common n or p-layer, respectively (with “n” standing for n-doped silicon or germanium, respectively and “p” for p-doped silicon or germanium, respectively).

The electrode connected with the common n- or p-layer, respectively, is called a base, and the two other electrodes are called emitter and collector.

By an appropriate controlling of the base potential and thus of the base current, the effect of the back to back diodes that is blocking for the electrodes or holes, respectively, can be eliminated, so that their conductivity increases by magnitudes.

So-called field effect transistors (FETs) are semiconductors that are, contrary to the above-mentioned bipolar transistors, controlled with an electric field, i.e. currentless (or almost currentless, respectively).

Field effect transistors (e.g. corresponding junction FETs, or MOSFETs (e.g. depletion or enhancement MOSFETs), etc.) comprise a control electrode (“gate”) by means of which the resistance between two further electrodes (“drain” and “source”) can be controlled.

Correspondingly similar to the above-mentioned differentiation in the case of bipolar transistors (npn or pnp bipolar transistors), there exist n-channel and p-channel FETs.

In the case of n-channel FETs, the channel current becomes the smaller, the further the gate potential decreases. In the case of p-channel FETs, this is the other way round.

Due to the almost currentless signal switching or amplifying, respectively, achieved by FETs (e.g. CMOS-FETs), they are often used in miniaturized microelectronic circuits.

For the manufacturing of the above-mentioned semiconductor field effect transistors and semiconductor bipolar transistors, an appropriate silicon (or germanium) monocrystal material is required as a substrate. This is relatively expensive.

In prior art, a plurality of different memory devices, in particular semiconductor devices, are known, e.g. so-called functional memory devices (e.g. PLAs, PALs, etc.) and so-called table memory devices, e.g. ROM devices (ROM=Read Only Memory)—in particular PROMs, EPROMs, EEPROMs, flash memories, etc.—, and RAM devices (RAM=Random Access Memory or read-write memory), e.g. DRAMs and SRAMs.

A RAM device is a memory for storing data under a predetermined address and for reading out the data under this address later.

Since it is intended to accommodate as many memory cells as possible in a RAM device, one has been trying to realize same as simple as possible.

In the case of SRAMs (SRAM=Static Random Access Memory), the individual memory cells consist e.g. of few, for instance 6, transistors, and in the case of so-called DRAMs (DRAM=Dynamic Random Access Memory) in general only of one single, correspondingly controlled capacitive element (e.g. a trench capacitor) with the capacitance of which one bit each can be stored as charge.

This charge, however, remains for a short time only. Therefore, a so-called “refresh” must be performed regularly, e.g. approximately every 64 ms.

In contrast to that, no “refresh” has to be performed in the case of SRAMs, i.e. the data stored in the memory cell remain stored as long as an appropriate supply voltage is fed to the SRAM.

In the case of non-volatile memory devices (NVMs), e.g. EPROMs, EEPROMs, and flash memories, the stored data remain, however, stored even when the supply voltage is switched off.

Furthermore, so-called resistive or resistively switching memory devices have also become known recently, e.g. so-called Phase Change Memories, PMC memories (PMC=Programmable Metallization Cell), CB memories (CB=Conductive Bridging), etc.

In the case of resistive or resistively switching memory devices, an “active” material—which is, for instance, positioned between two appropriate electrodes (i.e. an anode and a cathode)—is placed, by appropriate switching processes (more exactly: by appropriate current or voltage pulses of appropriate intensity and duration), in a more or less conductive state. The more conductive state corresponds e.g. to a stored, logic “One”, and the less conductive state to a stored, logic “Zero”, or vice versa.

In the case of so-called multilevel storing methods—in the form of several, different resistive states of the active material (achieved by appropriate current or voltage pulses)—more than 1 bit can also be stored per cell (e.g. 2, 3, or 4 bits per cell, wherein each resistive state is assigned to a corresponding bit size to be stored).

In the case of Phase Change Memories (PC memories), for instance, an appropriate chalcogenide compound may e.g. be used as an “active” material that is positioned between two corresponding electrodes (e.g. a Ge—Sb—Te or an Ag—In—Sb—Te compound).

The chalcogenide compound material is adapted to be placed in a (partially) amorphous, i.e. relatively weakly conductive, or a (partially) crystalline, i.e. relatively strongly conductive state by appropriate switching processes (wherein e.g. the relatively strongly conductive state may, for instance, correspond to a stored, logic “One”, and the relatively weakly conductive state may correspond to a stored, logic “Zero”, or vice versa).

Phase change memory cells are, for instance, known from G. Wicker, Nonvolatile, High Density, High Performance Phase Change Memory, SPIE Conference on Electronics and Structures for MEMS, Vol. 3891, Queensland, 2, 1999, and e.g. from Y. N. Hwang et al., Completely CMOS Compatible Phase Change Non-volatile RAM Using NMOS Cell Transistors, IEEE Proceedings of the Nonvolatile Semiconductor Memory Workshop, Monterey, 91, 2003, S. Lai et al., OUM-a 180 nm nonvolatile memory cell element technology for stand alone and embedded applications, IEDM 2001, etc.

In the case of PMC memories (PMC=Programmable Metallization Cell), for instance, when programming a corresponding PMC memory cell—depending on whether a logic “One” or a logic “Zero” is to be written into the cell—appropriate metal dendrites (e.g. of Ag, or Cu, etc.) are deposited in an active material positioned between two electrodes by means of appropriate current pulses of appropriate intensity and duration and by means of electrochemical reactions caused thereby (which results in a conductive state of the cell), or they are degraded (which results in a non-conductive state of the cell).

PMC memory cells are, for instance, known from Y. Hirose, H. Hirose, J. Appl. Phys. 47, 2767 (1975), and e.g. from M. N. Kozicki, M. Yun, L. Hilt, A. Singh, Electrochemical Society Proc., Vol. 99-13, (1999) 298, M. N. Kozicki, M. Yun, S. J. Yang, J. P. Aberouette, J. P. Bird, Superlattices and Microstructures, Vol. 27, No. 5/6 (2000) 485-488, and e.g. from M. N. Kozicki, M. Mitkova, J. Zhu, M. Park, C. Gopalan, “Can Solid State Electrochemistry Eliminate the Memory Scaling Quandry”, Proc. VLSI (2002), and R. Neale: “Micron to look again at non-volatile amorphous memory”, Electronic Engineering Design (2002).

Furthermore, so-called CB memories (CB=Conductive Bridging) are also known from prior art.

CB memories are described e.g. in Y. Hirose, H. Hirose, J. Appl. Phys. 47, 2767 (1975), T. Kawaguchi et al., “Optical, electrical and structural properties of amorphous Ag—Ge—S and Ag—Ge—Se films and comparison of photoinduced and thermally induced phenomena of both systems”, J. Appl. Phys. 79 (12), 9096, 1996, and e.g. in M. Kawasaki et al., “Ionic conductivity of Agx(GeSe3)1-x (0<x0.571) glasses”, Solid State Ionics 123, 259, 1999, etc.

In the case of CB memories, the switching process is based on that—by applying appropriate current pulses of appropriate intensity and duration—in an active material (e.g. an appropriate chalcogenide (e.g. GeSe, GeS, AgSe, CuS, etc.)) positioned between two electrodes, elements of a corresponding deposition “cluster” continue to increase in volume until the two electrodes are finally “bridged” in a conductive manner, i.e. are conductively connected with each other (conductive state of the CB cell).

By applying appropriate inverse current pulses, this process can be reversed again, so that the corresponding CB cell can again be returned to a non-conductive state.

It is an object of the invention to provide a novel switching or amplifier device, in particular a transistor, a method for the production thereof, and a novel method for operating a switching or amplifier device, respectively.

This and further objects are achieved by the subject matters of claims 1 and 11.

Advantageous further developments of the invention are indicated in the subclaims.

In accordance with a basic idea of the invention, there is provided a switching or amplifier device comprising:
an active material that is adapted to be placed in a more or less conductive state by means of appropriate switching processes; and
at least three electrodes or contacts, respectively.

Advantageously, the active material may, for instance, comprise a solid body electrolyte that may be arranged or manufactured, respectively, on or in a—preferably not monocrystalline—substrate.

The switching or amplifier device can thus be manufactured at distinctly less cost than conventional semiconductor switching or amplifier devices that are arranged or manufactured, respectively, on or in corresponding silicon (or germanium) monocrystal material.

In the following, the invention will be described in more detail by means of several embodiments and the enclosed drawing. The drawing shows:

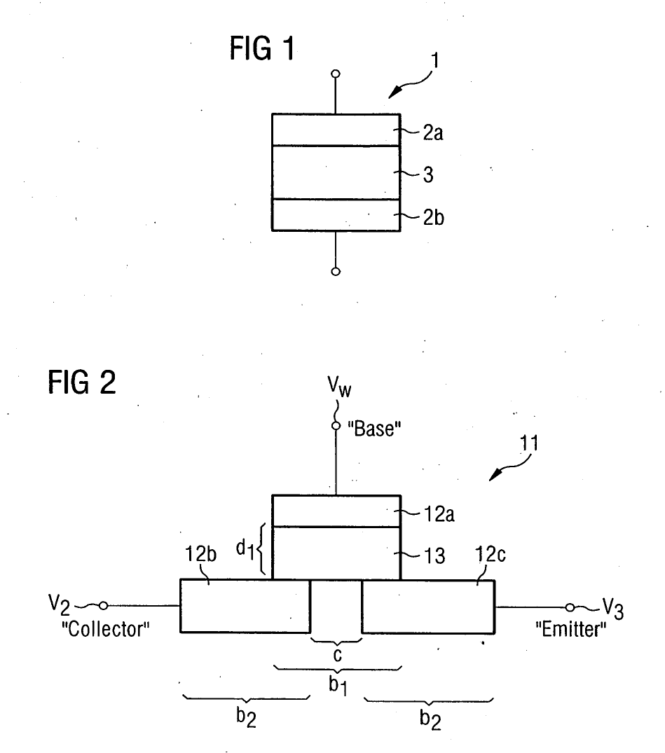

FIG. 1 a schematic cross-sectional representation of a resistively switching memory cell according to prior art;

FIG. 2 a schematic cross-sectional representation of a switching or amplifier device or transistor, respectively, according to an embodiment of the present invention;

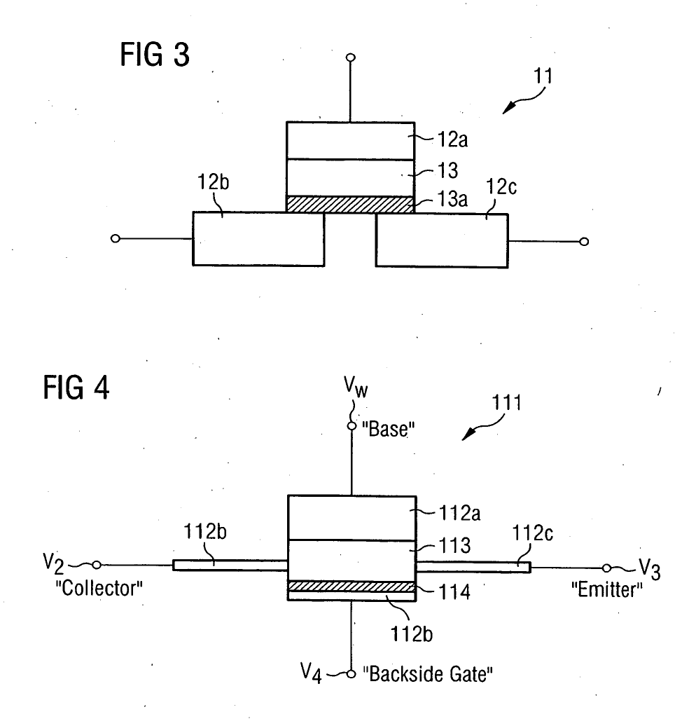

FIG. 3 the device illustrated in FIG. 2 in a low-resistance or conductive state, respectively;

FIG. 4 a schematic cross-sectional representation of a switching or amplifier device or transistor, respectively, according to a further embodiment of the present invention;

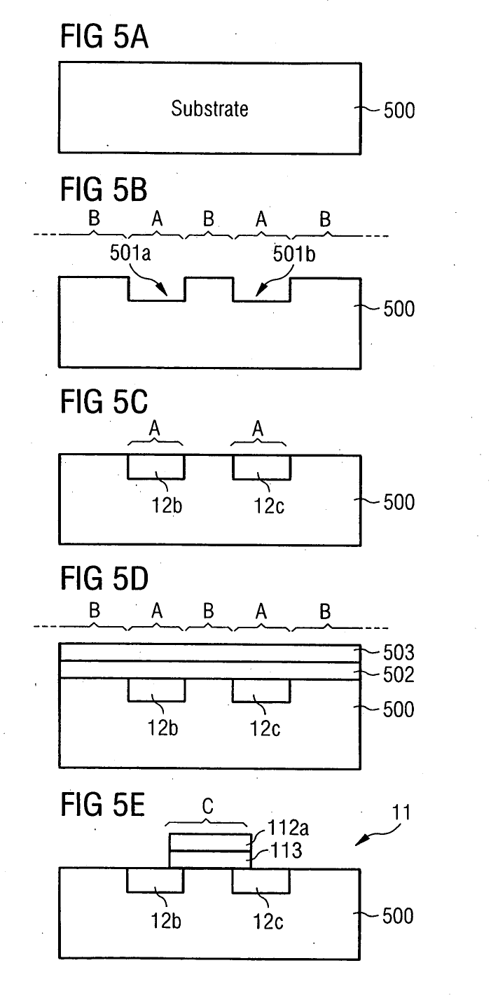

FIGS. 5a-5e the device illustrated in FIG. 2 and FIG. 3 at different phases during the manufacturing of the device;

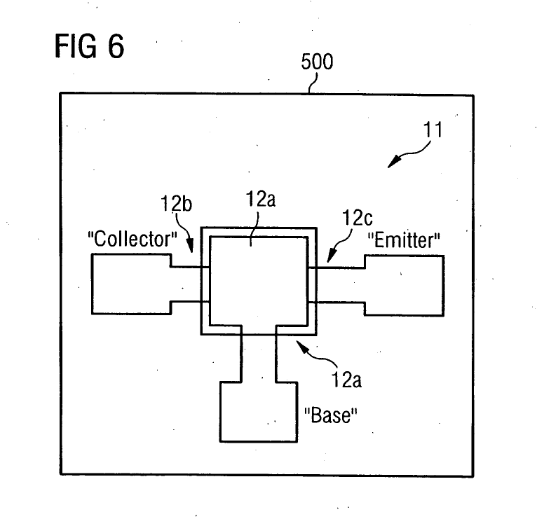

FIG. 6 the device illustrated in FIGS. 2, 3, and 5e, viewed from the top;

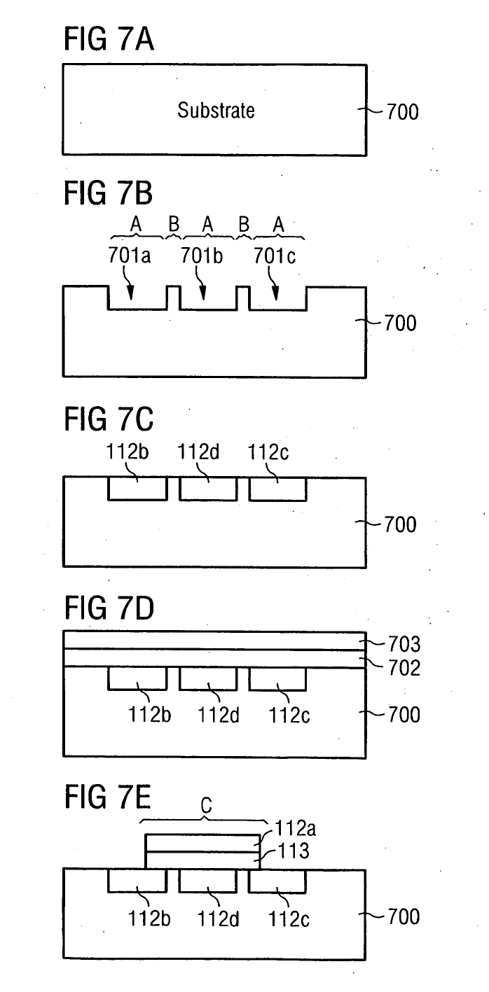

FIGS. 7a-7e the device illustrated in FIG. 4 at different phases during the manufacturing of the device; and

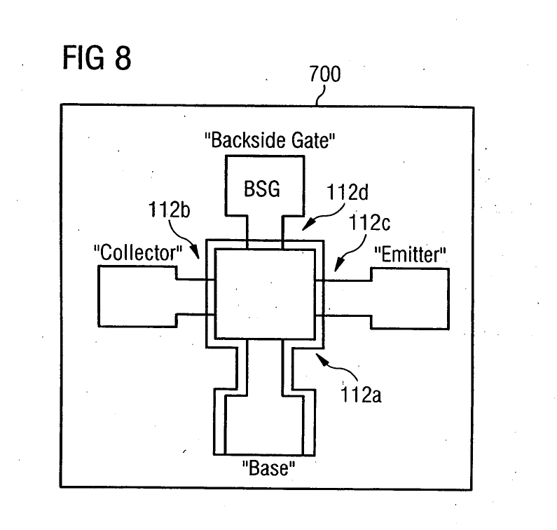

FIG. 8 the device illustrated in FIGS. 4 and 7e, viewed from the top.

FIG. 1 shows—purely schematically and by way of example—the structure of a resistively switching memory cell 1 according to prior art.

The memory cell 1 comprises two corresponding metal electrodes 2a, 2b (i.e. one anode and one cathode).

Between the electrodes, there is positioned a corresponding, “active” material layer 3.

The material layer 3 is adapted to be placed in a more or less conductive state by means of appropriate switching processes (in particular by applying appropriate current or voltage pulses of appropriate intensity and duration to the metal electrodes 2a, 2b) (wherein e.g. the more conductive state corresponds to a stored, logic “One” and the less conductive state to a stored, logic “Zero”, or vice versa).

The memory cell may, for instance, be a phase change memory cell, a CB memory cell (CB=Conductive Bridging), or a PMC memory cell (PMC=Programmable Metallization Cell).

With a phase change memory cell 1, e.g. an appropriate chalcogenide compound (e.g. a Ge—Sb—Te or an Ag—In—Sb—Te compound) may be used as an “active” material for the above-mentioned material layer 3.

The chalcogenide compound material is adapted to be placed, by appropriate switching processes (in particular by applying appropriate current or voltage pulses of appropriate intensity and duration to the metal electrodes 2a, 2b), in an amorphous, i.e. relatively weakly conductive, or in a crystalline, i.e. relatively strongly conductive, state (wherein e.g. the relatively strongly conductive state may correspond to a stored, logic “One” and the relatively weakly conductive state may correspond to a stored, logic “Zero”, or vice versa).

As a material for the upper and/or lower electrode 2a, 2b, an appropriate metal or an appropriate metal alloy may, for instance, be used, e.g. TiN, TiSiN, TiAlN, TaSiN, or TiW, etc., or e.g. tungsten, or any other, suitable electrode material.

In order to achieve, with the memory cell 1, a change from an amorphous, i.e. relatively weakly conductive state of the “active” material, to a crystalline, i.e. relatively strongly conductive state, an appropriate current pulse of appropriate intensity and duration may be applied to the electrodes 2a, 2b, resulting—due to the relatively high resistance of the active material layer 3—in that the active material layer 3 is correspondingly heated—beyond the crystallization temperature of the active material—which results in a crystallization of the corresponding regions of the active material layer 3 (“writing process”).

Vice versa, a change of state of the corresponding regions of the active material layer 3 from a crystalline, i.e. relatively strongly conductive state, to an amorphous, i.e. relatively weakly conductive state, may, for instance, be achieved in that—again by applying an appropriate current pulse of appropriate intensity and duration to the electrodes 2a, 2b—corresponding regions of the active material layer 3 are heated beyond the melting temperature of the active material layer 3 and are subsequently “quenched” to an amorphous state by quick cooling (“deleting process”).

If, for instance, a CB memory cell is used as memory cell 1, e.g. an appropriate chalcogenide (e.g. GeSe, GeS, AgSe, CuS, etc.) may be used as a material for the active material layer 3, and—for one of the electrodes, e.g. the electrode 2a—e.g. Cu, Ag, Au, Zn, etc., and—for the other electrode 2b—e.g. W, Ti, Ta, TiN, etc.

In the case of CB memory cells 1, the switching process is based on that—by applying appropriate current (or voltage) pulses of appropriate intensity and duration to the metal electrodes 2a, 2b—corresponding (Cu, Ag, Au, or Zn, etc.) deposition “clusters” continue to increase in volume in the active material layer 3 until the two electrodes 2a, 2b are finally conductively “bridged”, i.e. conductively connected with each other (conductive state of the CB memory cell 1).

By applying appropriate inverse current (or voltage) pulses, this process can be reversed again, so that the corresponding CB memory cell 1 may be returned to a non-conductive state.

FIG. 2 shows a schematic representation of a switching or amplifier device 11 (“transistor”) according to an embodiment of the present invention.

The switching or amplifier device 11 comprises three electrodes 12a, 12b, 12c which may—correspondingly similar as with conventional transistors—act as a “base” (electrode 12a), “collector” (electrode 12b), and “emitter” (electrode 12c).

Between the electrode 12a (“base”) that is positioned above (or, alternatively, e.g. below) the electrodes 12b, 12c (“collector”, “emitter”) and the electrodes 12b, 12c (“collector”, “emitter”) that are e.g. positioned substantially in one plane, an “active” material layer 13 is positioned, correspondingly similar as with “resistively switching” memory devices.

The “active” material layer 13 is, as will be explained in more detail in the following, adapted to be placed, by means of appropriate switching processes (here: currents/voltages applied to the electrodes 12a, 12b, 12c (cf. below)), in particular by heating currents caused thereby, in a more or less conductive state.

As active material layer 13, e.g. a solid body electrolyte may be used, and for the electrodes 12a, 12b, 12c appropriate metals/metal conductors.

Advantageously, for the three electrodes 12a, 12b, 12c, and for the active material layer 13, there may be used correspondingly similar materials as with “resistively switching” memory devices (in particular for the three electrodes 12a, 12b, 12c correspondingly similar materials as for the two electrodes of a corresponding “resistively switching” memory device, and for the active material layer 13 correspondingly similar materials as for the active material layer of the corresponding “resistively switching” memory device).

For instance—correspondingly similar as with PMC memory cells—a solid body electrolyte layer that is, for instance, saturated with an appropriate metal (e.g. Ag (or Cu)), i.e. comprises movable metal cations, in particular e.g. a chalcogenide layer (e.g. a GeSe or a GeS layer), may be used as active material layer 13, or any other, suitable ion conductor material layer such as WOx (or corresponding further amorphous or crystalline substances that have a correspondingly high metal cation conductivity in the solid phase).

For the (here: lower) electrodes 12b, 12c (acting as “collector” or “emitter”, respectively), (metal) electrodes that are, for instance, enriched or saturated with the above-mentioned metal, e.g. Ag (or Cu) and that can be oxidized, or e.g. Ag, Cu, etc., may be used—correspondingly similar e.g. as for the anode electrode with PMC memory cells—, and for the (here: upper) electrode 12a (acting as a “base”), any “indifferent” metal layer may be used—correspondingly similar e.g. as for the cathode electrode with PMC memory cells—(or—preferably—vice versa (i.e., for instance, Ag, Cu for the electrode 12a, and indifferent metals for the electrodes 12b, 12c)).

The dimensions of the electrode 12a may be chosen correspondingly similar to the dimensions of a cathode electrode with PMC memory cells. Similarly, the dimensions of the electrodes 12b and 12c, and of the active material layer 13 may also be chosen correspondingly similar to the dimensions of the anode electrode or of the active material layer, respectively, with PMC memory cells.

For instance, the active material layer 13 may merely have a thickness d1 of e.g. <160 nm, in particular e.g. <100 nm, preferably <80 nm, <60 nm, or <30 nm, and the electrodes may merely have a thickness of e.g. <200 nm, preferably <160 nm, <120 nm, or <60 nm.

The active material layer and/or the electrodes 12a, 12b, 12c may—viewed from the top—be e.g. of substantially square or circular (or e.g. rectangular) cross-section, etc. (or may—viewed from the top—have the cross-sectional shapes illustrated in FIG. 6).

The active material layer 13 and/or the electrodes each may have a—relatively small—length and/or breadth b1 or b2, respectively (wherein the length and/or breadth b1 or b2 may, for instance, be <400 nm, <200 nm, or <160, in particular e.g. <100 nm).

The electrodes 12b, 12c are arranged to be laterally spaced from each other, e.g. with a distance c of e.g. <100 nm, preferably <80 nm, <60 nm, <30 nm, or <15 nm.

As results from FIG. 2, the electrode 12a contacts, at its entire lower limiting area (or parts thereof) the upper limiting area of the active material layer 13, and a partial area of the upper limiting area of the electrode 12b (positioned at the right in the drawing) contacts (over the entire length of the active material layer 13, or parts thereof) a left partial area of the lower limiting area of the active material layer 13, and a partial area of the upper limiting area of the electrode 12c (positioned at the left in the drawing) contacts (over the entire length of the active material layer 13, or parts thereof) a right partial area of the lower limiting area of the active material layer 13.

Alternatively to the above-mentioned materials—e.g. correspondingly similar as, for instance, with phase change memory cells—e.g. corresponding Ge—Sb—Te or Ag—In—Sb—Te chalcogenide compounds may be used as active material layer 13, and for the electrodes—also correspondingly similar as e.g. with phase change memory cells—e.g. TiN, TiSiN, TiAIN, TaSiN, or TiW, etc., or e.g. tungsten, or any other, suitable electrode material, or e.g., and this is of particular advantage,—correspondingly similar as e.g. with CB memory cells—e.g. GeSe, GeS, SiSe, SiS, AgSe, or CuS chalcogenide (in particular e.g. Ge—Se:Ag, or Ge—S:Ag) as active material layer 13, and for the electrodes 12b, 12c—also correspondingly similar as e.g. with CB memory cells—e.g. W, Cu, Ag, Au, Zn, etc., and for the electrode 12a—also correspondingly similar as e.g. with CB memory cells e.g. Ti, W, Ta, TiN, Al, etc. (or vice versa).

By applying appropriate voltages/currents to the active material layer 13 via the three above-mentioned electrodes 12a, 12b, 12c (or by applying appropriate current and/or voltage pulses of appropriate intensity and duration), the material positioned between the three electrodes 12a, 12b, 12c may—similar as with switching processes known e.g. from PMC, CB, or phase change memory cells—be placed in a more or less conductive state (so that—optionally—e.g. the electrodes 12a and 12b, and/or the electrodes 12a and 12c, and/or the electrodes 12b and 12c, and/or the electrodes 12a, 12b, and 12c may be electrically connected (in a strongly conductive manner), or electrically separated (or not be connected or be connected in a weakly conductive manner only).

With an active material layer 13 that consists, for instance, of identical or similar material as with a PMC memory cell, there may—by applying appropriate currents/voltages to the electrodes 12a, 12b, 12c, and by electrochemical reactions caused thereby—be deposited corresponding metal “dendrites” (e.g. of Ag, or Cu, etc.) between the corresponding electrodes 12a, 12b, 12c (which results in a conductive connection between the corresponding electrodes 12a ,12b, 12c), or they may be degraded (which results in a non-conductive or only weakly conductive connection between the corresponding electrodes 12a, 12b, 12c).

Furthermore—alternatively—, with an active material layer 13 that consists, for instance, of an identical or similar material as with a phase change memory cell, the active material layer 13 may—by applying appropriate currents/voltages to the electrodes 12a, 12b, 12c—be placed in a crystalline state between corresponding electrodes 12a, 12b, 12c (which results in a conductive connection between the corresponding electrodes 12a, 12b, 12c), or in an amorphous state (which results in a non-conductive or only weakly conductive connection between the corresponding electrodes 12a, 12b, 12c).

With an additional, particularly advantageous alternative—e.g. with an active material layer 13 that consists, for instance, of an identical or similar material as with a CB memory cell—elements of a corresponding deposition “cluster” may—by applying appropriate currents/voltages to the electrodes 12a, 12b, 12c—continue to increase in volume in the active material layer 13 until corresponding electrodes 12a, 12b, 12c are conductively connected with each other; by applying inverse currents/voltages, this process may be reversed, so that the corresponding electrodes 12a, 12b, 12c are then not (any longer) conductively connected with each other or are connected with each other in a weakly conductive manner only.

Here, it may, for instance, be utilized that the chalcogenide material used in the material layer 13 may have a p-conductive, n-conductive, or metallic conductivity, depending on the doping with metal ions.

By applying appropriate voltages/currents to the electrodes 12a, 12b, 12c, the solid body electrolyte-based device 11 illustrated in FIGS. 2 and 3 (or slightly modified, as will be explained further below) may—correspondingly similar to conventional semiconductor bipolar transistors and/or semiconductor field effect transistors—in particular be operated as a switch and/or an amplifier, as will be explained in more detail in the following.

By applying a voltage +V_{w} to the electrode 12a, and a voltage +V₂ to the electrode 12b, and a voltage +V₃ to the electrode 12c (namely such that there applies: V_{w}−V₂>Vₜ, V_{w}−V₃>Vₜ, and V_{w}>0, V₂>0, V₃>0) it may, for instance, be achieved that, due to the above-mentioned effects, i) a current conductive channel is provided between the electrode 12b, and—finally—the electrode 12a, and ii) a current conductive channel is provided between the electrode 12c, and—finally—the electrode 12a, i.e. a current conductive channel between the electrode 12b and the electrode 12c is provided relatively quickly (cf. e.g. the transversely conductive area 13a illustrated in hatching in FIG. 3). The electrodes 12b and 12c are then short-circuited with low resistance, which may be examined by a corresponding selection of the voltages V₂, V₃ available at the electrodes 12b and 12c (“low resistance or conductive state” of the device 11).

The device 11 may thus be operated as an electrochemical voltage switch that “opens” in the case of effective base voltages that are larger than the redox potential of the active material used in the active material layer 13, i.e. changes to a low resistance or conductive state, respectively.

By a—subsequent—strong reducing or eliminating of the voltage V_{w} applied at the electrode 12a (so that, e.g., there applies: V_{w}=0V), the device 11 may, due to the above-mentioned (or correspondingly reversed) effects—caused by the potential difference between the voltage (V₂ or V₃, respectively, wherein there applies V₂>0 or V₃>0, respectively) applied at the electrode 12b or 12c, respectively, and the voltage applied at the electrode 12a (then e.g. V_{w}=0V)—be reset to a “high resistance or non-conductive state” (where the electrodes 12b and 12c are not connected with each other or in a weakly conductive manner only).

FIG. 4 is a schematic representation of a switching or amplifier device 111 (“transistor”) according to a further, alternative embodiment of the present invention.

The switching or amplifier device 111 comprises—similar to the device 11 illustrated in FIGS. 2 and 3 (and correspondingly similar to “resistively switching” memory devices)—an “active” material layer 113 and—also similar to the device 11 illustrated in FIGS. 2 and 3—electrodes 112a, 112b, 112c (which may act as a “base” (electrode 112a), “collector” (electrode 112b), and “emitter” (electrode 112c)), and—other than the device 11 illustrated in FIGS. 2 and 3—a further, additional electrode 112d (“backside gate”), and—optionally—an insulating layer 114 provided between the active material layer 113 and the further electrode 112d.

The active material layer 113 may be of a similar or identical design, and/or have similar or identical dimensions, and/or consist of similar or identical materials as the active material layer 13 of the device 11 illustrated in FIGS. 2 and 3.

Correspondingly, the four electrodes 112a, 112b, 112c, 112d may also be of a similar or identical design, and/or have similar or identical dimensions, and/or consist of similar or identical materials as the three electrodes 12a, 12b, 12c of the device 11 illustrated in FIGS. 2 and 3 (alternatively—as is illustrated in FIG. 4—the thickness of the electrodes 112b, 112c, 112d may, for instance, be somewhat smaller than the thickness of the electrodes 12b, 12c, etc. illustrated in FIGS. 2 and 3).

The electrodes 112b, 112c may—e.g. on the same level—be positioned at the right and at the left of the active material layer 113.

As results from FIG. 4, the electrode 112b contacts, at the entire lateral limiting area thereof (that is positioned at the right in the drawing) a middle portion of the lateral limiting area of the active material layer 113 (that is positioned at the left in the drawing).

Correspondingly similar, the electrode 112c contacts at the entire lateral limiting area thereof (that is positioned at the left in the drawing) a middle portion of the lateral limiting area of the active material layer 113 (that is positioned at the right in the drawing).

The upper limiting area of the insulating layer 114 contacts the lower limiting area of the active material layer 113, and the lower limiting area of the insulating layer 114 contacts the upper limiting area of the fourth electrode 112d.

In a preferred manner, the material used for the insulating layer 114 has a lower electrical conductivity, in particular an electrical conductivity that is by more than one third or a half lower, than the material used for the active material layer 113 (in particular in the above-mentioned strongly conductive state thereof), or e.g. a conductivity ranging between the conductivity of the active material layer 113 in the above-mentioned strongly conductive and in the above-mentioned weakly conductive state, e.g., a resistance between e.g. 1 kΩ and 1 GΩ, etc. (substantially independently of the currents/voltages applied at the electrodes 112a, 112b, 112c ,112d).

As an insulating layer 114, for instance, doped or relatively strongly doped chalcogenide (that thus has a relatively low electrical conductivity), e.g. a GeS, GeSe, or a GeTe chalcogenide, or a corresponding oxide, may be used (or, alternatively, e.g. a correspondingly doped or relatively strongly (oxygen- and/or nitrogen-) doped Ge—Sb—Te or Ag—In—Sb—Te compound, etc., that thus has a relatively low electrical conductivity).

By applying appropriate currents/voltages to the electrodes 112a, 112b, 112c, 112d, the solid body electrolyte-based device 111 illustrated in FIG. 4 may, as will be explained in more detail in the following—correspondingly similar to conventional semiconductor bipolar transistors and/or semiconductor field effect transistors—be operated as a switch and/or an amplifier.

By applying a voltage +V_{w} to the electrode 112a and connecting the electrode 112d e.g. to ground (with e.g. V₄=0 V, wherein there applies: V_{w}-V₄>Vₜ) it may, for example, be achieved (in fact possibly without applying corresponding voltages V₂, V₃ to the electrodes 112b, 112c) that, due to the above-mentioned effects, a current conductive channel is established between the electrodes 112a, 112d—the electrodes 112b and 112c are then short-circuited at low resistance, which may be examined by, a corresponding selection of the voltages V₂, V₃ applied at the electrodes 112b and 112c (“low-resistance or conductive state” of the device 111).

By a—subsequent—strong reducing or eliminating of the voltage V_{w} applied at the electrode 112a (so that there applies e.g.: V_{w}=0 V), the device 111 may, due to the above-mentioned (or correspondingly reversed) effects—caused, for instance, by a potential difference between the voltage (V₂ or V₃, respectively, with V₂>0 and V₃>0) applied at the electrode 112b or 112c, respectively (then e.g. V_{w}=0V)—be reset to a “high-resistance or non-conductive state” (in which the electrodes 112b and 112c are not connected with each other or are connected with each other in a weakly conductive manner only).

Alternatively, the device 111 may, for instance, also be operated as a memory device, in particular a non-volatile memory device, e.g. in that the device 111 is written “permanently” by means of relatively long lasting, and/or by means of relatively strong, and/or by means of relatively many current pulses, so that the respectively stored data are (corresponding to a more or less strongly conductive state of the device 111) no longer deleted even after the reducing or eliminating of the voltages applied at the electrode 112a and/or the electrodes 112b, 112c, 112d.

FIGS. 5a to 5e show the device 11 illustrated in FIG. 2 and FIG. 3 at different phases during the manufacturing of the device 11.

As is illustrated in FIG. 5a and FIG. 5b, at regions A at which the electrodes 12b, 12c are to be manufactured, an appropriate material layer is removed from a substrate 500 and is left at regions B positioned therebetweeen (i.e. corresponding recesses 501a, 501b are produced in the regions A).

For selectively removing the substrate 500 at the regions A, any conventional methods may be used, e.g. appropriate photo-lithographic methods or methods based on masked etching (where the regions A, but not the regions B (or corresponding regions of a photoresist layer provided above the substrate 500) are exposed and are then etched away (together with the regions A of the substrate 500 positioned below the corresponding, exposed regions of the photoresist layer) (whereupon the photoresist layer is removed again)).

As a material for the substrate 500, any electrically insulating materials may, on principle, be used, in particular those that are not too rough or are relatively smooth, respectively (e.g. glass)—other than with conventional semiconductor devices, no relatively expensive silicon (or germanium) monocrystal materials thus have to be used as a substrate material.

As is illustrated in FIG. 5c, for manufacturing the electrodes 12b, 12c, an appropriate electrode material, e.g. W (or Al, etc.) is filled or deposited, respectively, in the recesses 501a, 501b previously produced in the substrate 500 at the regions A.

Subsequently, an appropriate planarizing step may be performed.

Alternatively to the manufacturing method described here, a corresponding electrode material layer may, for instance—instead of the method step illustrated in FIG. 5b—be first of all deposited above the substrate 500 illustrated in FIG. 5a, and the—continuous—electrode material layer that has been produced such may subsequently be structured and be removed at regions that correspond to the above-mentioned regions B (e.g. again by using appropriate photo-lithographic methods or methods based on masked etching).

As deposition methods, e.g. any conventional deposition methods may be used, e.g. appropriate sputtering methods (or e.g. vacuum deposition, CVD, PLD, ALD, spin-coating, or spray-coating methods, etc.).

Following the method step illustrated in FIG. 5c, as is shown in FIG. 5d—in the manufacturing method described here—, a corresponding—continuous—doped solid body electrolyte layer 502 (e.g. Ge—Se:Ag) is deposited above the electrodes 12a, 12b or the above-mentioned regions A, respectively, and above the regions B adjacent thereto, and thereabove—for manufacturing the electrode 12a—a corresponding metal layer 503 (e.g. a layer of titanium).

Alternatively, the solid body electrolyte layer 502 may, for instance, be doped after the deposition only.

As deposition methods—again—e.g. any conventional deposition methods may be used, e.g. appropriate sputtering methods (or e.g. vacuum deposition, CVD, PLD, ALD, spin-coating, or spray-coating methods, etc.).

The—continuous—layers 502, 503 produced such are subsequently structured as is indicated in FIG. 5e, and are then removed correspondingly (here: at regions C)—e.g. again by using appropriate photo-lithographic methods or methods based on masked etching—, so that, finally, the device 11—that is illustrated from the top in FIG. 6 (and has already been described above making reference to FIGS. 2 and 3)—is produced.

FIGS. 7a to 7e show the device 111 illustrated in FIG. 4 (or a device with a correspondingly similar design) at different phases during the manufacturing of the device.

As is illustrated in FIG. 7a and FIG. 7b, a corresponding material layer is removed from a substrate 700 at regions A at which the electrodes 12b, 12c, 12d are to be manufactured, and is left at regions B positioned therebetween (i.e. corresponding recesses 701a, 701b, 701c are produced at the regions A).

For selectively removing the substrate 700 at the regions A, any conventional methods may be used, e.g. appropriate photo-lithographic methods or methods based on masked etching.

As a material for the substrate 700, any electrically insulating materials may, on principle, be used, in particular materials that are not too rough or are relatively smooth, respectively (e.g. glass)—other than with conventional semiconductor devices, no relatively expensive silicon (or germanium) monocrystal materials thus have to be used as a substrate material.

As is illustrated in FIG. 7c, an appropriate electrode material, e.g. W (or Al, etc.) is filled or deposited, respectively, in the recesses 701a, 701b, 701c previously produced at the regions A in the substrate 700.

Subsequently, an appropriate planarizing step may be performed.

Alternatively to the manufacturing method described here—instead of the method step illustrated in FIG. 7b—a corresponding electrode material layer may first of all be deposited above the substrate 700 illustrated in FIG. 7a, and the—continuous—electrode material layer produced such may subsequently be structured and be removed at regions corresponding to the above-mentioned regions B (e.g. again by using appropriate photo-lithographic methods or methods based on masked etching).

Following the method step illustrated in FIG. 7c, as is shown in FIG. 7d—in the manufacturing method described here—, a corresponding—continuous—doped solid body electrolyte layer 702 (e.g. Ge—Se:Ag) is deposited above the electrodes 112a, 112b, 112c—for manufacturing the active material layer 13—and thereabove—for manufacturing the electrode 112a—a corresponding metal layer 703 (e.g. a layer of titanium).

Alternatively, the solid body electrolyte layer 702 may be doped after the deposition only.

As deposition methods, any conventional deposition methods may be used, e.g. appropriate sputtering methods (or e.g. vacuum deposition, CVD, PLD, ALD, spin-coating, or spray-coating methods, etc.).

The—continuous—layers 702, 703 are—as is indicated in FIG. 7e—structured and are then removed correspondingly (here: at regions C)—e.g. again by using appropriate photo-lithographic methods or methods based on masked etching—, so that, finally, the device 111—that is illustrated from the top in FIG. 8 (and has already been described above making reference to FIG. 4 (or a correspondingly similar device))—is produced.

By using the above-mentioned—preferably non-mono-crystal-line—substrate 500, 700, e.g. glass, it is possible to manufacture the devices 11, 111 at substantially less costs than conventional semiconductor switching or amplifier devices that are arranged or manufactured, respectively, on or in corresponding silicon (or germanium) monocrystalline material.

### LIST OF REFERENCE SIGNS

1 memory cell
2a electrode
2b electrode
3 active material layer
11 transistor
12a electrode
12b electrode
12c electrode
13 active material layer
13a transversely conductive region
111 transistor
112a electrode
112b electrode
112c electrode
112d electrode
113, active material layer
114 insulating layer
500 substrate
501a recess
501b recess
502 solid body electrolyte layer
503 metal layer
700 substrate
701a recess
701b recess
701c recess
702 solid body electrolyte layer
703 metal layer

1. A switching or amplifier device (11, 111) comprising:
an active material (13, 113) that is adapted to be placed in a more or less conductive state and/or a state having a more or less high capacity, by means of appropriate switching processes; and
at least three electrodes or contacts (12a, 12b, 12c).

2. The switching or amplifier device (11, 111) according to claim 1, wherein said active material (13, 113) comprises a solid body electrolyte.

3. The switching or amplifier device (11, 111) according to claim 1, wherein said active material (13, 113) comprises a chalcogenide or a chalcogenide compound, respectively.

4. The switching or amplifier device (11, 111) according to claim 3, wherein said active material (13, 113) is positioned between said at least three electrodes or contacts (12a, 12b, 12c).

5. The switching or amplifier device (11, 111) according to claim 1, wherein said active material (13, 113) is electrically connected with said at least three electrodes or contacts (12a, 12b, 12c).

6. The switching or amplifier device (11, 111) according to claim 5, said switching or amplifier device (11, 111) being designed and equipped such that said active material (13, 113) is adapted to be placed in a more or less conductive state and/or a state having a more or less high capacity by applying appropriate voltages/currents to one or several electrodes or contacts (12a, 12b, 12c).

7. The switching or amplifier device (11, 111) according to claim 6, wherein said active material (13, 113) and/or said electrodes or contacts (12a, 12b, 12c) are positioned or manufactured, respectively, on or in a substrate material (500, 700), in particular along with a plurality of further switching or amplifier devices.

8. The switching or amplifier device (11, 111) according to claim 7, wherein said substrate material (500, 700) is or comprises no monocrystal material, in particular no silicon or germanium monocrystal material.

9. The switching or amplifier device (11, 111) according to claim 7, wherein said substrate material (500, 700) is or comprises glass, and/or a foil, and/or paper.

10. The switching or amplifier device (111) according to claim 9, said switching or amplifier device (111) comprising at least four electrodes or contacts (112a, 112b, 112c, 112c).

11. A method for operating a switching or amplifier device (11, 111) comprising an active material (13, 113) that is adapted to be placed in a more or less conductive state by means of appropriate switching processes, and at least three electrodes or contacts (12a, 12b, 12c), wherein the method comprises the following step:
applying appropriate currents and/or voltages to one or several ones of said at least three electrodes or contacts (12a, 12b, 12c), so that said active material (13, 113) is placed in a more or less conductive state and/or a state having a more or less high capacity.

12. The method according to claim 11, said method additionally comprising the following step:
evaluating the state of said active material (13, 113) after it has been placed in said more or less conductive state.

13. The method according to claim 12, wherein, during the evaluation of the state of said active material (13, 113), the resistance and/or the capacity of said active material (13, 113) is evaluated.

14. The method according to claim 11, said method additionally comprising the following step:
eliminating or reducing, respectively, the voltages applied at one or several ones of said at least three electrodes or contacts (12a, 12b, 12c), so that said active material (13, 113) is reset to a more or less conductive state.

15. A system comprising: a switching or amplifier device (11, 111) according to claim 1, as well as control means, for performing a method according to claim 1.
